(19) United States
(12) Patent Application Publication
(10) Pub. No.: US 2026/0090283 A1
(43) Pub. Date: Mar. 26, 2026

(54) SHADOW EVAPORATION ON LATTICE PLANES FOR TUNNEL JUNCTIONS

(71) Applicant: INTERNATIONAL BUSINESS MACHINES CORPORATION, Armonk, NY (US)

(72) Inventors: Marco Turchetti, White Plains, NY (US); Santino Carnevale, Stamford, CT (US)

(21) Appl. No.: 18/892,634

(22) Filed: Sep. 23, 2024

(51) Int. Cl. H10N 60/01; H10N 60/12; H10N 60/80

(52) U.S. Cl. CPC H10N 60/0912; H10N 60/12; H10N 60/805

(57) ABSTRACT

A structure that includes a Josephson Junction located on a substrate. The Josephson Junction includes a first electrode, a second electrode, and a tunnel junction located between the first electrode and the second electrode. The tunnel junction is located in a recess of the substrate and herein the recess is based on the crystalline lattice of the substrate.

### BACKGROUND

The present invention generally relates to the field of quantum chips, and more particularly to a design for a qubit.

Superconducting quantum computing systems can comprise one or more superconducting qubits. These qubits are generally formed by a nonlinear inductor (Josephson Junction) in parallel with shunting capacitors.

### BRIEF SUMMARY

Additional aspects and/or advantages will be set forth in part in the description which follows and, in part, will be apparent from the description, or may be learned by practice of the invention.

A structure that includes a Josephson Junction located on a substrate. The Josephson Junction includes a first electrode, a second electrode, and a tunnel junction located between the first electrode and the second electrode. The tunnel junction is located in a recess of the substrate and herein the recess is based on the crystalline lattice of the substrate.

A structure includes a trench located in a substrate. The substrate includes a first flat surface located at the top of the trench and a second flat surface located in the bottom of the trench. The trench includes a plurality of angled sidewalls. A first electrode located on the first flat surface of the substrate, along the second flat surface located at the bottom of the trench, and along one of the plurality of angled sidewalls of the trench. A tunnel junction located on top of the first electrode located on the second flat surface of the substrate located at the bottom of the trench. A second electrode located on top of tunnel junction layer and located on one of the plurality of angled sidewalls of the trench.

A method includes utilizing an anisotropic etch to form a trench in a substrate. Utilizing a first angled evaporation process to form a first electrode. Oxidizing the first electrode to form a tunnel junction. Utilizing a second angled evaporation process to form a second electrode. The second electrode, the tunnel junction, and the first electrode overlap at the bottom of the trench.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top-down view of the Josephson Junction after an initial stage of processing, in accordance with the embodiment of the present invention.

FIG. 2 illustrates cross-section X of the Josephson Junction after the initial stage of processing, in accordance with the embodiment of the present invention.

FIG. 3 illustrates a top-down view of the Josephson Junction after formation and patterning of a lithography layer and the formation of a trench in the substrate, in accordance with the embodiment of the present invention.

FIG. 4 illustrates cross-section X of the Josephson Junction after formation and patterning of a lithography layer and the formation of a trench in the substrate, in accordance with the embodiment of the present invention.

FIG. 5 illustrates a top-down view of the Josephson Junction after removal of the lithography layer, in accordance with the embodiment of the present invention.

FIG. 6 illustrates cross-section X of the Josephson Junction after removal of the lithography layer, in accordance with the embodiment of the present invention.

FIG. 7 illustrates a top-down view of the Josephson Junction after an angled evaporation process, in accordance with the embodiment of the present invention.

FIG. 8 illustrates cross-section X of the Josephson Junction after an angled evaporation process, in accordance with the embodiment of the present invention.

FIG. 9 illustrates a top-down view of the Josephson Junction after formation of an oxidized layer, in accordance with the embodiment of the present invention.

FIG. 10 illustrates cross-section X of the Josephson Junction after formation of an oxidized layer, in accordance with the embodiment of the present invention.

FIG. 11 illustrates a top-down view of the Josephson Junction after a second angled evaporation process, in accordance with the embodiment of the present invention.

FIG. 12 illustrates cross-section X of the Josephson Junction after a second angled evaporation process, in accordance with the embodiment of the present invention.

FIG. 13 illustrates a top-down view of the Josephson Junction after separating the first metal layer and the second metal layer, in accordance with the embodiment of the present invention.

FIG. 14 illustrates cross-section X of the Josephson Junction after separating the first metal layer and the second metal layer, in accordance with the embodiment of the present invention.

FIG. 15 illustrates a top-down view of the Josephson Junction illustrate design parameters to calculate the properties of the Josephson Junction, in accordance with the embodiment of the present invention.

FIG. 16 illustrates cross-section X of the Josephson Junction illustrate design parameters to calculate the properties of the Josephson Junction, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will be packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout.

Superconducting quantum computing systems can comprise one or more superconducting qubits. These qubits are generally formed by a nonlinear inductor (Josephson Junction) in parallel with shunting capacitors. A Josephson Junction (JJ) is a junction between two superconductors separated by a thin insulating layer. JJs require ad-hoc processing techniques involving ion milling, shadow evaporation over a Dolan Bridge, and lift-off patterning. This is not ideal for two reasons: it is not compatible for large scale manufacturing and introduces non-idealities and high process variability that can negatively affect the system performance.

The present invention is directed towards the formation of a Josephson Junction by utilizing an angled evaporation technique. The present invention exploits the lattice planes, lattice orientation, or crystalline structure of the substrate to form trenches in the substrate. For example, an anisotropic wet etch process can be utilized to form a trench in a substrate that is comprised of (100)-oriented crystal substrate, such that the walls of the trench correspond to (111) planes. This generates planes or angled surfaces that act as a side boundary of the trench.

Utilizing the (111) planes of the substrate to form the sidewalls of the trench is one way to do this, but it can be achieved by other means. The trench could be formed with a similar shape that does not correspond to specific lattice planes and the idea would still work. It is well within the skill level of one of ordinary skill in the art to utilize one or more etching process to form a trench with angled sidewalls.

The trench has a depth or extends downwards to create a low surface or a valley in the substrate. Angled evaporation is utilized to form different metal plates, where the material is deliver/deposited/evaporated at an angle to the top surface of the substrate. The valleys/trenches create a shadow region or a region where the metal material will not be deposited based on the angle of the delivered material (evaporation angle). A first plate is formed by utilizing a first evaporation angle and a second plate is formed by utilizing a second evaporation angle, where the first and second evaporation angles are different. The first metal layer is oxidized to form an insulating layer or oxide layer or a tunnel junction. A Josephson Junction (JJ) is formed where the first and second plate overlap where the oxide layer is sandwiched between the first metal layer and the second metal layer, where the first metal layer and the second metal layer are comprised of a superconductor material.

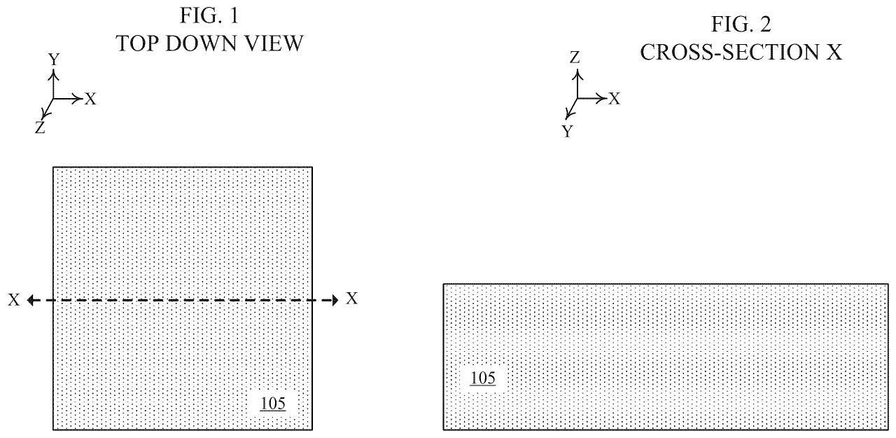

FIG. 1 illustrates a top-down view of Qubit, in accordance with the embodiment of the present invention. FIG. 2 illustrates cross-section X which extends horizontally through the qubit.

Referring now to FIGS. 1 and 2 illustrate the processing stage after the formation of initial layers for the Qubit. FIG. 2 illustrates cross-section X that shows substrate 105.

The substrate 105 can be, for example, a material including, but not necessarily limited to, silicon (Si), silicon germanium (SiGe), Si:C (carbon doped silicon), carbon doped silicon germanium (SiGe:C), III-V, II-V compound semiconductor or another like semiconductor. In addition, multiple layers of the semiconductor materials can be used as the semiconductor material of substrate 105. In some embodiments, substrate 105 includes both semiconductor materials and dielectric materials. The semiconductor substrate 105 may also comprise an organic semiconductor or a layered semiconductor such as, for example, Si/SiGe, a silicon-on-insulator or a SiGe-on-insulator. A portion or the entire semiconductor substrate 105 may also be comprised of an amorphous, polycrystalline, or monocrystalline. The semiconductor substrate 105 may be doped, undoped or contain doped regions and undoped regions therein.

Assuming that substrate 105 is comprised of, for example, a crystal that has a (100) orientation, which will lead to the formation of trenches 115 with the (111) sidewalls (the formation of the trenches 115 will be described in further details below). Substrate 105 can be comprised of materials that have a different orientation, for example, (111) substrate, but then the trench 115 would have a different final structure than what is illustrated in the Figures.

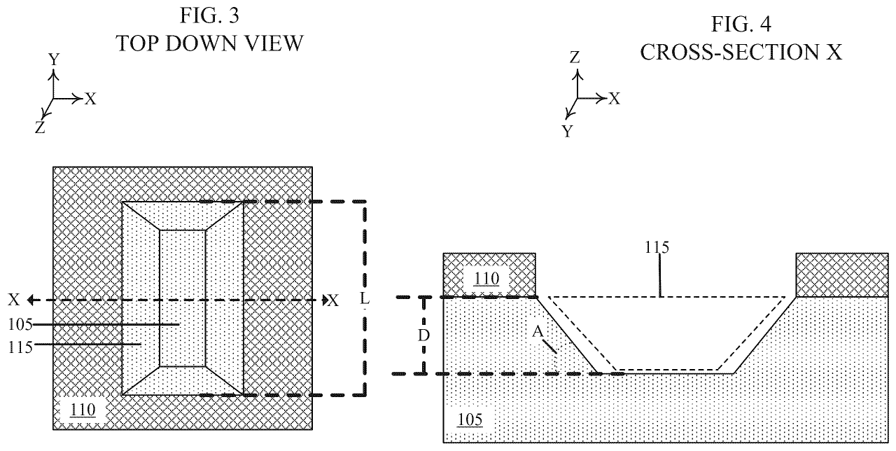

FIGS. 3 and 4 illustrate the processing stage after formation and patterning of a lithography layer 110 and the formation of a trench 115 in the substrate 105. Lithography layer 110 is formed on top of substrate 105. The lithography layer 110 can be spun on, sputtered on, or formed by another means. The lithography layer 110 is patterned or developed to expose portions of the substrate 105. FIG. 3 illustrates the portion of the lithography layer 110 that was removed to expose a portion of the substrate 105. Anisotropic etching process, for example, TMAH or KOH, is used to form the trench 115. The anisotropic etching process is able to take advantage of the lattice orientation or crystalline structure of the substrate 105 to form a trench 115 that has angled sidewalls. The trench 115 as a depth D and a length L as indicated in FIGS. 3 and 4. The sidewalls of trench 115 form an acute angle A as indicated in FIG. 4. Acute angle A can be in the range of about 40 to 70 degrees.

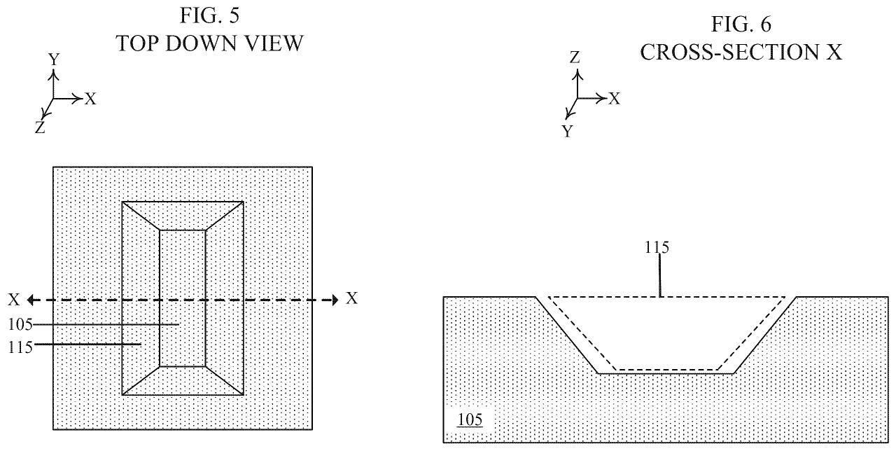

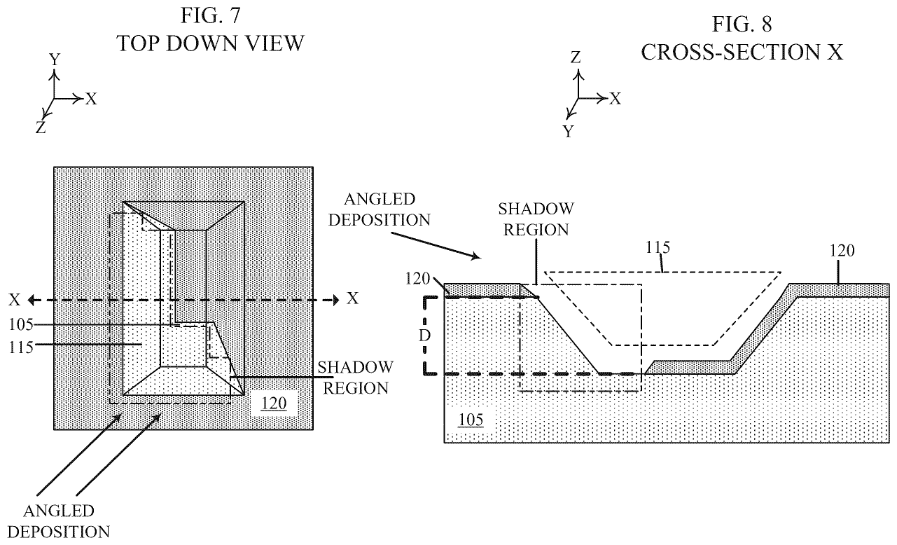

FIGS. 5 and 6 illustrate the processing stage after the removal of the lithography layer 110. The lithography layer 110 is removed to expose the top surface of substrate 105. FIGS. 7 and 8 illustrate the processing stage after an angled evaporation process. An angled metal deposition process, for example, metal deposited by evaporation in a tool that allows the substrate 105 to be tilted, is utilized to form a first metal layer 120. The first metal layer 120 is comprised of a superconducting material. For example, the first metal layer 120 can be comprised of a material selected from a group consisting of Al, Nb, Ta, Ti, TiN, W. The angled evaporation process deposited material at an angle from the top surface of substrate 105. The angle of the evaporation process creates a shadow region in trench 115. The shadow region is created from a combination of the angle and direction of the angled evaporation/deposition process and the depth D of the trench 115. A shadow region is a region where the first metal layer 120 is prevented from forming or a region where the deposited superconducting material will not be deposited. The first metal layer 120 is formed on the top surface of substrate 105 and along portions of the boundaries of the trench 115 that do not fall within the shadow region. However, the first metal layer 120 is not formed in the shadow region of trench 115.

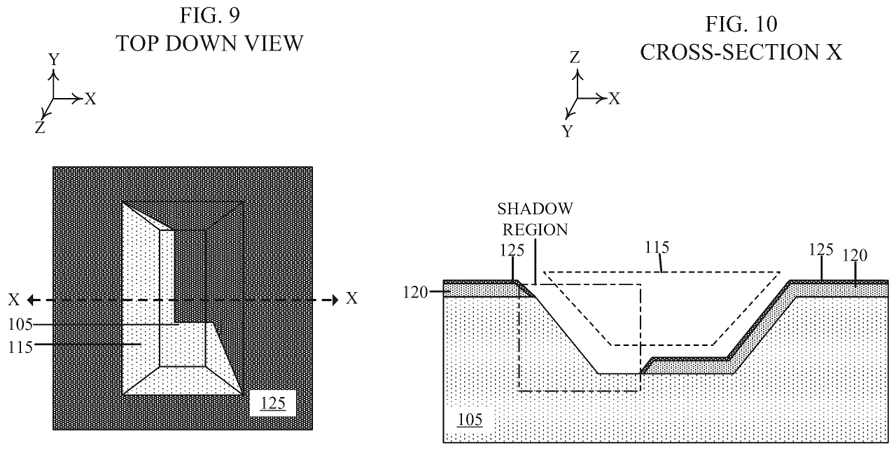

FIGS. 9 and 10 illustrate the processing stage after formation of an oxidized layer 125. The top or exposed surfaces of the first metal layer 120 are oxidized to for the oxide layer 125. The oxide layer 125 will act as an insulating layer or as a tunnel junction.

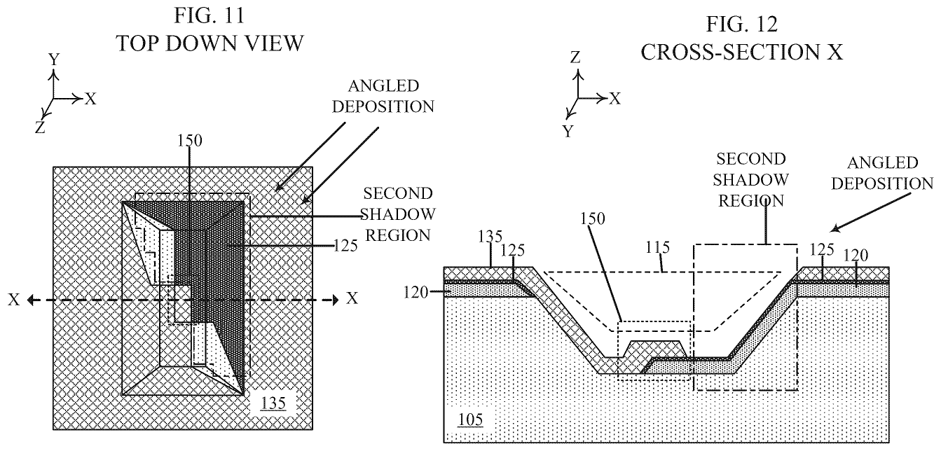

FIGS. 11 and 12 illustrate the processing stage after a second angled evaporation process. The second angled evaporation process is different than the process to form the first metal layer 120. An angled metal deposition process, for example, metal deposited by evaporation in a tool that allows the substrate 105 to be tilted, is utilized to form a second metal layer 135. The second metal layer 135 is comprised of a superconducting material. For example, the second metal layer 135 can be comprised of a material selected from a ground consisting of Al, Nb, Ta, Ti, TiN, W. The angle of evaporation/deposition for the second process to form the second metal layer 135 is different than the angle of evaporation/deposition used to form the first metal layer 120. The change in the angle of evaporation/deposition will cause the shadow region to move and create a second shadow region. The second shadow region is created from a combination of the angle and direction of the angled evaporation/deposition process and the depth D of the trench 115. A second shadow region is a region where the second metal layer 135 is prevented from forming or a region where the deposited superconducting material will not be deposited. The second metal layer 135 is formed on the top of the oxide layer 125 and along portions of the boundaries of the trench 115 (e.g., the substrate 105) located in the shadow region from the first angled evaporation/deposition process. However, the second metal layer 120 is not formed in the second shadow region of trench 115. The second metal layer 135 forms on a top of the oxide layer 125 forming an overlap region 150 located in the trench 115 An overlap region 150 is formed, where the overlap region 150 is located in trench 115 that includes the first metal layer 120, the oxide layer 125, and the second metal layer 135. The overlap region 150 will also be referred to as the Josephson Junction, where the Josephson Junction (JJ) is a junction between two superconductors (i.e., the first metal layer 120 and the second metal layer 135) separated by a thin insulating layer or tunnel junction (i.e., the oxide layer 125).

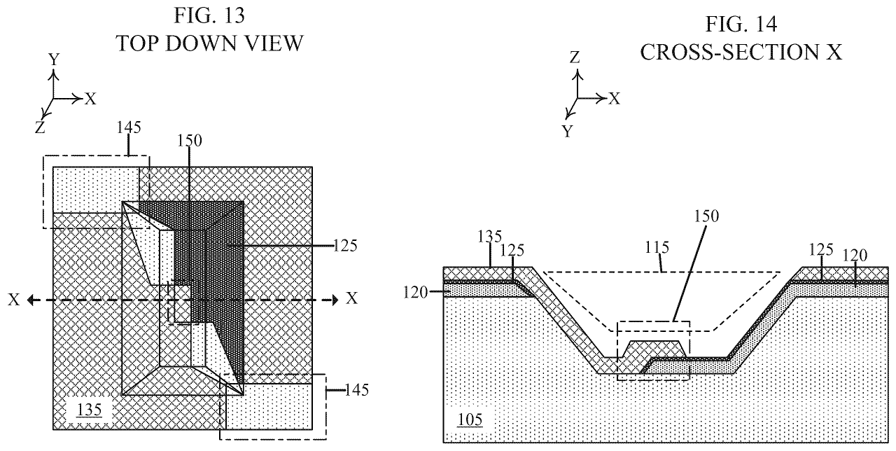

FIGS. 13 and 14 illustrate the processing stage after separating the first metal layer 120 and the second metal layer 135. The first metal layer 120 and the second metal layer 135 are separated from each other as emphasized by dashed boxes 145. Separation is necessary to separate the metal plates (i.e., the first metal layer 120 and the second metal layer 135) from each other. This separation can be accomplished by utilizing a lithography layer and an etching process, a lift-off method, or another etching process. One or more metallization features (not shown) are used to raise the qubit to its excited state as well as perform readout of its state. Superconducting qubits are excited through capacitive or inducting coupling, rather than a direct, galvanic connection to the incoming signal in order to reduce leakage and environmental noise. The first metal layer 120 will act as a first electrode and the second metal layer 135 will act as a second electrode. The first metal layer 120 has an angled surface located on the first side of the trench 115 and the second metal layer has an angled surface located on a second side of the trench 115. The angled surface of the first metal layer 120 and the angled surface of the second metal layer 135 are opposite each other. The first metal layer 120 and the second metal layer 135 do not overlap along the angled sidewalls of the trench 115. The first metal layer 120 and the second metal layer 130 extend along a bottom flat surface (e.g., the substrate 105) of trench 115, such that the overlap region 150 is located in the bottom of trench 115.

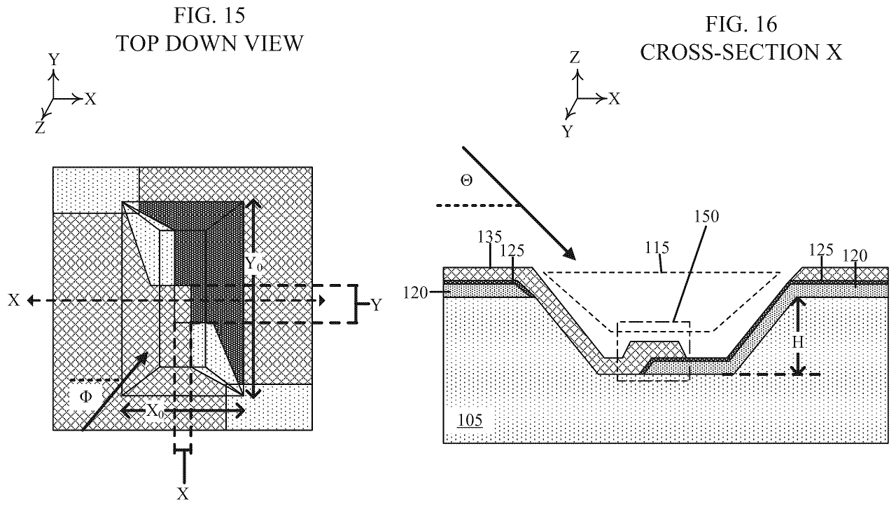

FIGS. 15 and 16 illustrate design parameters to calculate the properties of the Josephson Junction 150. Considering X₀, Y₀ the size of the trench, and φ, θ the horizontal and vertical evaporation angles, we can calculate the dimensions of the junction as:

$$X = {X}_{0} - 2 H \frac{cos ( Φ )}{tan ( Θ )} \qquad Equation ( 1 )$$

$$Y = {Y}_{0} - 2 H \frac{sin ( Φ )}{tan ( Θ )} \qquad Equation ( 2 )$$

### Wherein

$$ϕ = θ = \frac{π}{4}$$

and X₀=Y₀=L₀ and X=Y=L=L₀−\sqrt{2}H. The minimum distance between two junctions is \sqrt{2}H.

At

$$ϕ = θ = \frac{π}{4}$$

and X₀=Y₀=L, if we have an error δj on each of these quantities we can calculate the effect on the final dimension on the junction as:

$$δ L = δ {L}_{0} + \sqrt{2} δ H + \sqrt{2} H δ ϕ + 2 \sqrt{2} H δ θ \qquad Equation ( 3 )$$

So, for example, if H=100 nm an error of 1 degree in the angle φ would generate a small error of 2.5 nm in the dimension L of the junction.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A structure comprising:
a Josephson Junction located on a substrate, wherein the Josephson Junction includes a first electrode, a second electrode, and a tunnel junction located between the first electrode and the second electrode, wherein the tunnel junction is located in a recess of the substrate, and herein the recess is based on the crystalline lattice of the substrate.

2. The structure of claim 1, wherein the recess in the substrate includes angled sidewalls and a flat bottom surface.

3. The structure of claim 2, wherein the first electrode is located on a first angled sidewall of the recess and is located on top of the flat bottom surface of the recess.

4. The structure of claim 3, wherein the tunnel junction is located on top of the first electrode located on top of the flat bottom surface of the recess.

5. The structure of claim 4, wherein the second electrode is located on a second angled sidewall of the recess and is located on top of the flat bottom surface of the recess.

6. The structure of claim 5, wherein the second electrode extends over a portion of the tunnel junction and the first electrode located on top of the flat bottom surface of the recess.

7. A structure comprising:
a trench located in a substrate, wherein the substrate includes a first flat surface located at the top of the trench and a second flat surface located in the bottom of the trench, wherein the trench includes a plurality of angled sidewalls;
a first electrode located on the first flat surface of the substrate, along the second flat surface located at the bottom of the trench, and along one of the plurality of angled sidewalls of the trench;
a tunnel junction located on top of the first electrode located on the second flat surface of the substrate located at the bottom of the trench;
a second electrode located on top of tunnel junction layer and located on one of the plurality of angled sidewalls of the trench.

8. The structure of claim 7, further comprising:
an overlap region located in the bottom recess, wherein the overlap region is a region where the second electrode is located on top of the tunnel junction and the first electrode.

9. The structure of claim 8, wherein the first electrode that is located along one of the plurality of angled sidewalls of the trench is in direct contact with the angled sidewall.

10. The structure of claim 9, wherein the second electrode that is located along one of the plurality of angled sidewalls of the trench is in direct contact with the angled sidewall.

11. The structure of claim 10, wherein the second electrode and first electrode do not overlap along the plurality of angled sidewalls of the trench.

12. The structure of claim 11, wherein the first electrode located on one of the angled sidewalls of the trench is located opposite to the second electrode located on one of the angled sidewalls of the trench.

13. The structure of claim 7, wherein the tunnel junction is further located on top of the first electrode that is located on the first flat surface of the substrate that is located at the top of the trench.

14. The structure of claim 12, wherein the second electrode is located on top of the tunnel junction located on the first flat surface of the substrate located at the top of the trench.

15. A method comprising:
utilizing an anisotropic etch to form a trench in a substrate;
utilizing a first angled evaporation process to form a first electrode;
oxidizing the first electrode to form a tunnel junction; and
utilizing a second angled evaporation process to form a second electrode, wherein the second electrode, the tunnel junction, and the first electrode overlap at the bottom of the trench.

16. The method of claim 15, wherein the first angled evaporation process utilizes a first deposition angle to deposit a first material of the first electrode.

17. The method of claim 16, wherein the first deposition angle causes a first shadow region to form within the trench, wherein the first material is prevented from forming the first electrode within the shadow region.

18. The method of claim 17, wherein the second angled evaporation process utilizes a second deposition angle to deposit a second material of the second electrode.

19. The method of claim 18, wherein the second deposition angle causes a second shadow region to form within the trench, wherein the second material is prevented from forming the second electrode within the second shadow region.

20. The method of claim 15, wherein trench formed by the anisotropic etch process takes advantage of the crystalline structure of the substrate.
